(19) United States
(12) Patent Application Publication
(10) Pub. No.: US 2026/0362948 A1
(43) Pub. Date: Nov. 12, 2026

(54) ELECTRONIC APPARATUS AND METHOD OF MANUFACTURING THE SAME

(71) Applicant: Samsung Display Co., LTD., Yongin-si (KR)

(72) Inventor: JOOHYEON LEE, Yongin-si (KR)

(21) Appl. No.: 19/629,837

(22) Filed: Mar. 26, 2026

(30) Foreign Application Priority Data
May 12, 2025 (KR) 10-2025-0061249

(51) Int. Cl. H10K 59/80; H10K 59/12; H10K 102/00

(52) U.S. Cl. CPC H10K 59/873; H10K 59/1201; H10K 2102/311

(57) ABSTRACT

An electronic apparatus includes a display module, a window including a bottom surface, including a concave portion and a flat portion, and disposed on the display module, and a coating layer disposed between the display module and the window. The coating layer includes a first coating layer being in contact with the concave portion and the display module and a second coating layer being in contact with the flat portion and the display module, and the first coating layer includes a tackifier layer derived from an oligomer including an alkyl group having 5 carbon atoms to 20 carbon atoms. The first coating layer has a storage modulus smaller than or equal to about 0.1 megapascal (Mpa) at room temperature, and the second coating layer has a tensile modulus greater than or equal to about 1 MPa and smaller than or equal to about 100 MPa at room temperature.

This application claims priority to Korean Patent Application No. 10-2025-0061249, filed on May 12, 2025, and all the benefits accruing therefrom under 35 U.S.C. § 119, the content of which in its entirety is herein incorporated by reference.

### BACKGROUND

### 1. Field

The disclosure relates to an electronic apparatus with excellent folding reliability, impact resistance, and display quality and a method of manufacturing the electronic apparatus.

### 2. Description of Related Art

Various types of electronic apparatuses, such as television sets, mobile phones, tablet computers, game units, or the like, are being developed. Recently, flexible electronic apparatuses that include a flexible display panel capable of folding, rolling, or sliding are being developed. Different from a rigid electronic apparatus, the flexible electronic apparatus is able to be folded, rolled, or bent. Since the shape of the flexible electronic apparatus is capable of being changed in various ways, the flexible electronic apparatus is easy to carry regardless of its screen size, thus improving user convenience. Components to maintain reliability for flexible operations are desired in the flexible electronic apparatus.

### SUMMARY

The disclosure provides an electronic apparatus with excellent folding reliability, impact resistance, and display quality.

The disclosure provides a method of manufacturing the electronic apparatus, which exhibits excellent processability.

An embodiment of the inventive concept provides an electronic apparatus including a display module including a folding part and a non-folding part next (adjacent) to the folding part, a window including a top surface and a bottom surface disposed between the top surface and the display module and disposed on the display module, and a coating layer disposed between the display module and the window. The bottom surface includes a concave portion that overlaps with the folding part and is concave downward and a flat portion that overlaps with the non-folding part, the coating layer includes a first coating layer being in contact with the concave portion and the display module and a second coating layer being in contact with the flat portion and the display module, the first coating layer includes a tackifier layer derived from an oligomer including an alkyl group having 5 carbon atoms to 20 carbon atoms and has a storage modulus smaller than or equal to about 0.1 megapascal (Mpa) at room temperature, and the second coating layer has a tensile modulus greater than or equal to about 1 MPa and smaller than or equal to about 100 MPa at room temperature.

In an embodiment, a difference between a refractive index of the window and a refractive index of the coating layer is smaller than or equal to about 0.2.

In an embodiment, the first coating layer has a thickness greater than or equal to about 60 micrometers (μm) and smaller than or equal to about 120 μm, and the second coating layer has a thickness greater than or equal to about 10 μm and smaller than or equal to about 30 μm.

In an embodiment, the thickness of the first coating layer is greater than the thickness of the second coating layer.

In an embodiment, a sum of a thickness of the concave portion and the thickness of the first coating layer is equal to a sum of a thickness of the flat portion and the thickness of the second coating layer.

In an embodiment, the first coating layer includes a polymer derived from a first resin composition including the oligomer, and the second coating layer includes a polymer derived from a second resin composition including the oligomer.

In an embodiment, the oligomer has a glass transition temperature greater than or equal to 80 degrees Celsius (°C) and smaller than or equal to 120 °C.

In an embodiment, a creep measured 1 hour after a manufacturing time point of the coating layer is greater than or equal to 0.05 times and smaller than or equal to 0.2 times of a creep measured at the manufacturing time point of the coating layer.

In an embodiment, the coating layer has a recovery rate greater than or equal to about 90% after undergoing 100 cycles of tensile tests.

In an embodiment, the first coating layer further includes an elastic layer, the tackifier layer contacts the concave portion of the window, and the elastic layer is disposed between the tackifier layer and the display module.

In an embodiment, the top surface of the window is flat.

An embodiment of the inventive concept provides a method of manufacturing an electronic apparatus. The method includes preparing a window including a top surface and a bottom surface disposed between the top surface and a display module and including a concave portion and a flat portion, which are defined in the bottom surface, before providing a coating layer and the window on the display module including a folding part and a non-folding part next (adjacent) to the folding part, and forming the coating layer including a first coating layer and a second coating layer on the bottom surface of the window. The forming the coating layer includes providing a liner film including a first area overlapping with the concave portion and a second area overlapping the flat portion on the bottom surface of the window, removing the first area of the liner film, providing a first resin composition in the concave portion and irradiating a first light to the first resin composition to form a preliminary first coating layer, removing the second area of the liner film, and providing a second resin composition on the flat portion and irradiating a second light to form the first coating layer and the second coating layer. The concave portion is concave downward and overlaps with the folding part, and the flat portion overlaps with the non-folding part.

In an embodiment, the first coating layer includes a tackifier layer derived from an oligomer including an alkyl group having 5 carbon atoms to 20 carbon atoms.

In an embodiment, the forming the coating layer includes forming the tackifier layer, and the forming the tackifier layer includes providing the first resin composition including the oligomer, moving the oligomer to the concave portion during the irradiating the first light, and curing the oligomer after the irradiating the second light.

In an embodiment, the first resin composition has a thickness that is a sum of a depth of the concave portion and a thickness of the liner film, and the second resin composition has a thickness equal to the thickness of the liner film.

In an embodiment, a difference between a dispersion force of the first resin composition and a dispersion force of the window is greater than or equal to 8 and smaller than or equal to 13, and a difference between a dispersion force of the second resin composition and the dispersion force of the window is greater than or equal to 8 and smaller than or equal to 13.

In an embodiment, according to the electronic apparatus of the disclosure, the first coating layer and the second coating layer are disposed under the window, which includes the concave portion and the flat portion, and the first coating layer includes a tackifier. Thus, the electronic apparatus has excellent folding reliability, impact resistance, and display quality.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a block diagram of an embodiment of an electronic apparatus of the disclosure;

FIG. 2 is a schematic view of embodiments of various electronic apparatuses of the disclosure;

FIG. 3A is a perspective view of an embodiment of an electronic apparatus of the disclosure;

FIG. 3B is a perspective view of an embodiment of an electronic apparatus of the disclosure;

FIG. 3C is a plan view of an embodiment of an electronic apparatus of the disclosure;

FIG. 3D is a perspective view of an embodiment of an electronic apparatus of the disclosure;

FIG. 4 is an exploded perspective view of an embodiment of an electronic apparatus of the disclosure;

FIG. 5 is a cross-sectional view taken along line I-I′ of FIG. 4;

FIG. 6 is a cross-sectional view of an embodiment of an electronic apparatus of the disclosure;

FIG. 7 is an enlarged view of an area XX′ of FIG. 5;

FIG. 8A is a diagram showing whether an interface between a resin composition and a window is visible;

FIG. 8B is a diagram showing whether an interface between a resin composition and a window is visible;

FIG. 9 is a cross-sectional view taken along line II-II′ of FIG. 4;

FIG. 10A is a flowchart showing an embodiment of a method of manufacturing an electronic apparatus of the disclosure;

FIG. 10B is a flowchart showing an embodiment of a method of manufacturing an electronic apparatus of the disclosure;

FIG. 11A is a view showing an embodiment of a process of the manufacturing method of the electronic apparatus of the disclosure;

FIG. 11B is a view showing an embodiment of a process of the manufacturing method of the electronic apparatus of the disclosure;

FIG. 11C is a view showing an embodiment of a process of the manufacturing method of the electronic apparatus of the disclosure;

FIG. 11D is a view showing an embodiment of a process of the manufacturing method of the electronic apparatus of the disclosure;

FIG. 11E is a view showing an embodiment of a process of the manufacturing method of the electronic apparatus of the disclosure; and

FIG. 11F is a view showing an embodiment of a process of the manufacturing method of the electronic apparatus of the disclosure.

### DETAILED DESCRIPTION

In the disclosure, it will be understood that when an element (or area, layer, or portion) is referred to as being “on”, “connected to” or “coupled to” another element or layer, it may be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc., may be used herein to describe various elements, these elements should not be limited by these terms. These terms are only used to distinguish one element from another element. Thus, a first element discussed below could be termed a second element without departing from the teachings of the disclosure. As an example, without departing from the scope of the disclosure, a first component, a first part, a first region, a first layer, and a first portion are referred to as a second component, a second part, a second region, a second layer, and a second portion, respectively, and vice versa. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the drawing figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

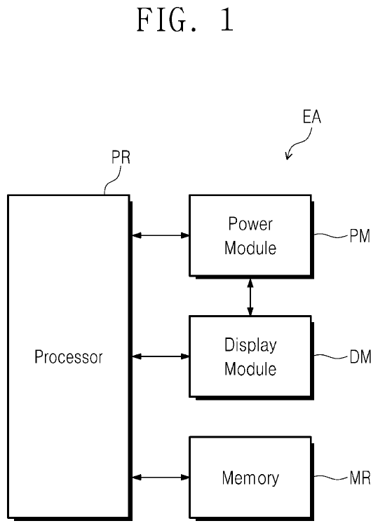

FIG. 1 is a block diagram of an embodiment of an electronic apparatus EA of the disclosure. The electronic apparatus EA may include a display module DM. The electronic apparatus EA may further include at least one of a processor PR, a memory MR, and a power module PM. Referring to FIG. 1, the electronic apparatus EA may include the display module DM, the processor PR, the memory MR, and the power module PM.

The processor PR may include at least one of a central processing unit (“CPU”), an application processor (“AP”), a graphics processing unit (“GPU”), a communication processor (“CP”), an image signal processor (“ISP”), and a controller.

The memory MR may store data information desired for the operation of the processor PR or the display module DM. When the processor PR executes an application stored in the memory MR, an image data signal and/or an input control signal may be transmitted to the display module DM, and the display module DM may process the received signals to output image information through a display screen.

The power module PM may include a power supply module, such as a power adapter or a battery device, and a power conversion module that converts power supplied by the power supply module to generate power desired for the operation of the electronic apparatus EA.

At least one of the above-described components of the electronic apparatus EA may be included in display devices in embodiments described below. In addition, among individual modules that are functionally included within a single module, some may be included in the display device while others may be provided separately from the display device. In an embodiment, the display device may include the display module DM, while the processor PR, the memory MR, and the power module PM may not be included in the display device but may be provided as separate devices within the electronic apparatus EA.

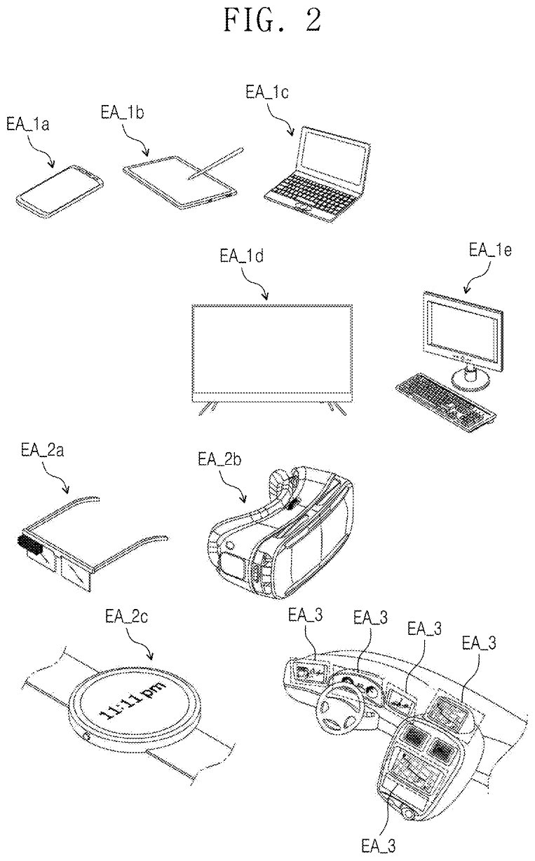

FIG. 2 is a schematic view illustrating embodiments of various electronic apparatuses of the disclosure. Referring to FIG. 2, various electronic apparatuses to which the display devices in embodiments of the disclosure are applied may include not only an electronic apparatus to display images, such as a smartphone EA_1a, a tablet PC EA_1b, a laptop computer EA_1c, a television EA_1d, a desktop monitor EA_1e, etc., but also a wearable electronic apparatus including a display module, such as a smart glasses EA_2a, a head-mounted display EA_2b, a smartwatch EA_2c, etc., and an in-vehicle electronic apparatus EA_3 including a display module, such as an instrument panel, a center fascia, a dashboard-mounted center information display (“CID”), or a room mirror display.

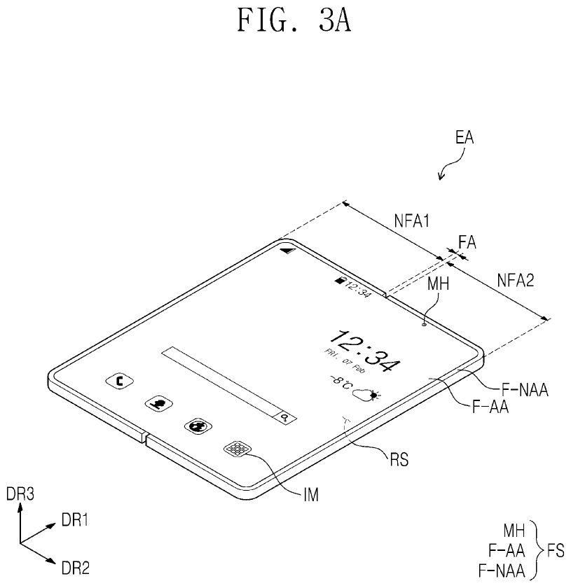

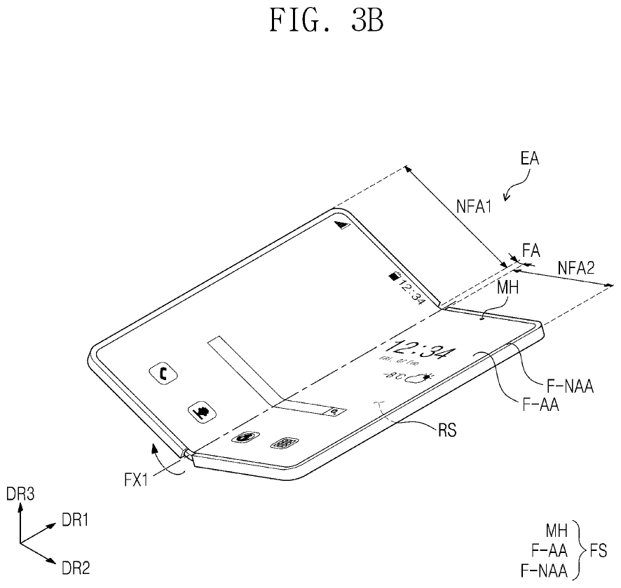

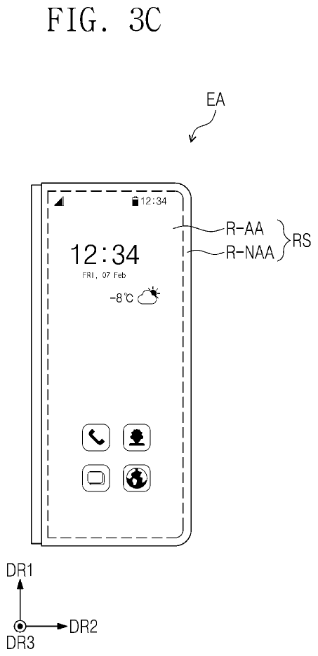

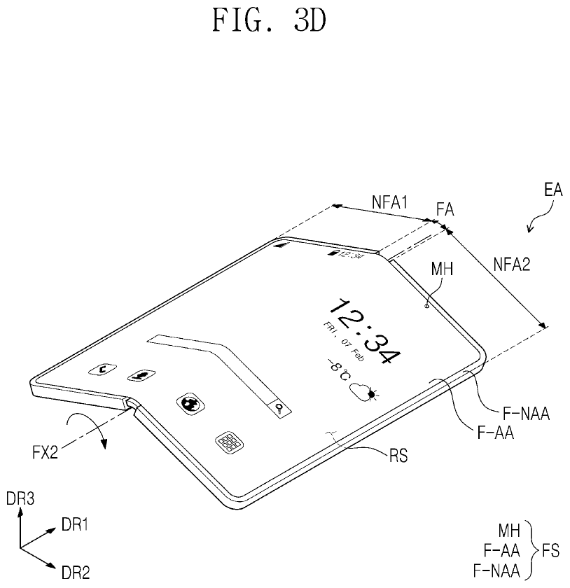

FIG. 3A is a perspective view of an embodiment of the electronic apparatus EA in an unfolded state of the disclosure. The electronic apparatus EA may be a device that is activated in response to electrical signals. In an embodiment, the electronic apparatus EA may be a smartphone, a tablet computer, a car navigation unit, a game unit, or a wearable device, however, it should not be limited thereto or thereby. FIG. 3A shows the smartphone as an illustrative embodiment of the electronic apparatus EA.

The electronic apparatus EA may include a first display surface FS defined by a first directional axis DR1 and a second directional axis DR2 intersecting the first directional axis DR1. The electronic apparatus EA may provide an image IM to a user through the first display surface FS. The electronic apparatus EA may display the image IM toward a third directional axis DR3 through the first display surface FS, which is substantially parallel to each of the first directional axis DR1 and the second directional axis DR2. The image IM may include a video and a still image.

In the disclosure, the first directional axis DR1 may be perpendicular to the second directional axis DR2, and the third directional axis DR3 may be a normal line direction with respect to a plane defined by the first directional axis DR1 and the second directional axis DR2. A thickness direction of the electronic apparatus EA may be substantially parallel to the third directional axis DR3. The thickness direction of the electronic apparatus EA may be assigned with the same reference numeral as the third directional axis DR3. A front surface (or upper surface) and a rear surface (or lower surface) may be opposite to each other in the third directional axis DR3, and a normal line direction of each of the front surface (or upper surface) and the rear surface (or lower surface) may be substantially parallel to the third directional axis DR3. The front surface (or upper surface) may refer to a surface next (adjacent) to the first display surface FS, and the rear surface (or lower surface) may refer to a surface spaced apart from the first display surface FS. In addition, the rear surface (or lower surface) may refer to the surface that is close to a second display surface RS, which will be described later. An upward direction may refer to a direction approaching the first display surface FS, and a downward direction may refer to a direction moving away from the first display surface FS.

A cross-section may refer to a flat surface parallel to the third directional axis (hereinafter also referred to as a thickness direction) DR3, and a plane may refer to a flat surface perpendicular to the thickness direction DR3. The plane may refer to a flat surface defined by the first directional axis DR1 and the second directional axis DR2.

In the disclosure, directions indicated by the first, second, and third directional axes DR1, DR2, and DR3 are relative to each other and may be changed to other directions. In addition, directions indicated by the first, second, and third directional axes DR1, DR2, and DR3 may also be described as the first, second, and third directions, and the same reference numerals may be used.

The electronic apparatus EA may sense an external input applied from outside the electronic apparatus EA. The external input may include various types of inputs provided from the outside of the electronic apparatus EA. In an embodiment, the external inputs may include an external input (e.g., hovering) applied when in proximity to or approaching close to the electronic apparatus EA at a predetermined distance as well as a contact by a part of a user's body such as a hand, for example. In addition, the external inputs may be provided in various forms such as force, pressure, temperature, light, etc.

The electronic apparatus EA may include the first display surface FS and the second display surface RS. The first display surface FS may include a first active area F-AA and a first peripheral area F-NAA. The first display surface FS may further include a sub-area MH. The second display surface RS may be opposite to at least a portion of the first display surface FS. That is, the second display surface RS may be defined as a portion of a rear surface of the electronic apparatus EA.

The first active area F-AA may be activated in response to the electrical signals. The image IM may be displayed through the first peripheral area F-NAA, and various external inputs may be sensed through the first active area F-AA.

The first peripheral area F-NAA may be defined next (adjacent) to the first active area F-AA. The first peripheral area F-NAA may have a light transmittance lower than a light transmittance of the first active area F-AA. The first peripheral area F-NAA may have a color. The first peripheral area F-NAA may surround the first active area F-AA. Accordingly, the first active area F-AA may have a shape that is substantially defined by the first peripheral area F-NAA, however, this is merely one example. The first peripheral area F-NAA may be defined next (adjacent) to only one side of the first active area F-AA or may be omitted.

An external object may be sensed through the sub-area MH of the display surfaces FS and RS, or a sound signal, such as a voice, may be provided to the outside through the sub-area MH of the display surfaces FS and RS. An optical signal such as a visible light or infrared light may travel through the sub-area MH.

Various electronic modules may be disposed in the sub-area MH. In an embodiment, the electronic module may include at least one of a camera, a speaker, an optical sensor, and a thermal sensor, for example. The electronic apparatus EA may include the electronic module that captures an external image using the visible light passing through the sub-area MH or that determines the proximity of an external object using the infrared light. The electronic module may include multiple components, and it should not be particularly limited.

The sub-area MH may be defined in the first active area F-AA, however, this is merely one of embodiments. In an embodiment, the sub-area MH may be surrounded by the first peripheral area F-NAA or may be surrounded by the first active area F-AA and the first peripheral area F-NAA. FIG. 3A shows one sub-area MH, however, the sub-area MH may be provided in plural.

The electronic apparatus EA may include at least one folding area FA and a plurality of non-folding areas NFA1 and NFA2 extending from the folding area FA. In an embodiment, a first non-folding area NFA1, the folding area FA, and a second non-folding area NFA2 may be sequentially defined along the second directional axis (also referred to as second direction) DR2. The folding area FA may be disposed between the first non-folding area NFA1 and the second non-folding area NFA2 in the second direction DR2. The first non-folding area NFA1 may be disposed next (adjacent) to one side of the folding area FA, and the second non-folding area NFA2 may be disposed next (adjacent) to an opposite side of the folding area FA. In an embodiment, the first non-folding area NFA1 may be disposed next (adjacent) to one side of the folding area FA in the second direction DR2, and the second non-folding area NFA2 may be disposed next (adjacent) to an opposite side of the folding area FA in the second direction DR2.

FIG. 3A shows the structure in which the electronic apparatus EA includes one folding area FA as an illustrative embodiment, however, the disclosure should not be limited thereto or thereby, and the electronic apparatus EA may include a plurality of folding areas defined therein. In an embodiment, the electronic apparatus may include two or more folding areas, and may also include three or more non-folding areas, with each of the folding areas disposed between two non-folding areas.

FIG. 3B is a perspective view illustrating an embodiment of a folding operation of the electronic apparatus EA of the disclosure. FIG. 3C is a plan view of an embodiment of the electronic apparatus EA in a folded state of the disclosure. FIG. 3D is a perspective view illustrating an embodiment of a folding operation of the electronic apparatus EA of the disclosure.

Referring to FIG. 3B, the electronic apparatus EA may be folded with respect to a first folding axis FX1 extending in the first directional axis (also referred to as a first direction) DR1. When the electronic apparatus EA is folded, the folding area FA may have a curvature and a radius of curvature. The electronic apparatus EA may be inwardly folded (in-folding) with respect to the first folding axis FX1 so that the first non-folding area NFA1 faces the second non-folding area NFA2 and the first display surface FS is not exposed to the outside.

FIG. 3C is a plan view showing the electronic apparatus EA that is inwardly folded. Referring to FIG. 3C, the second display surface RS may be visible to the user when the electronic apparatus EA is inwardly folded. In this case, the second display surface RS may include a second active area R-AA through which images are displayed. The second active area R-AA may be activated in response to electrical signals. The images may be displayed through the second active area R-AA, and various external inputs may be sensed through the second active area R-AA.

A second peripheral area R-NAA may be defined next (adjacent) to the second active area R-AA. The second peripheral area R-NAA may have a light transmittance lower than a light transmittance of the second active area R-AA. The second peripheral area R-NAA may have a color. The second peripheral area R-NAA may surround the second active area R-AA. Although not shown in drawing figures, the electronic apparatus EA may further include a sub-area in which an electronic module including various components is disposed in the second display surface RS.

Referring to FIG. 3D, the electronic apparatus EA may be folded with respect to a second folding axis FX2 extending in the first direction DR1. The electronic apparatus EA may be outwardly folded (out-folding) with respect to the second folding axis FX2 so that the first display surface FS is exposed to the outside. The electronic apparatus EA may repeat the unfolding operation and the in-folding operation or to repeat the unfolding operation and the out-folding operation, however, the disclosure should not be limited thereto or thereby.

FIGS. 3A to 3D show the electronic apparatus EA folded with respect to one folding axis FX1 or FX2, however, the number of the folding axes and the number of non-folding areas should not be particularly limited. In an embodiment, the electronic apparatus EA may be folded with respect to multiple folding axes so that a portion of the first display surface FS faces a portion of the second display surface RS. In addition, the first and second folding axes FX1 and FX2 are shown as being parallel to long sides of the electronic apparatus EA in the above embodiments, however, the disclosure should not be limited thereto or thereby. In an embodiment, the first and second folding axes FX1 and FX2 may be substantially parallel to short sides of the electronic apparatus EA.

In the electronic apparatus EA, the first non-folding area NFA1 and the second non-folding area NFA2 may be defined as areas including the display surfaces FS and RS parallel to the plane defined by the first directional axis DR1 and the second directional axis DR2 in the folded state as shown in FIG. 3C, and the folding area FA may be defined as an area between the first non-folding area NFA1 and the second non-folding area NFA2. The folding area FA may include a curved portion that has a curvature in the folded state.

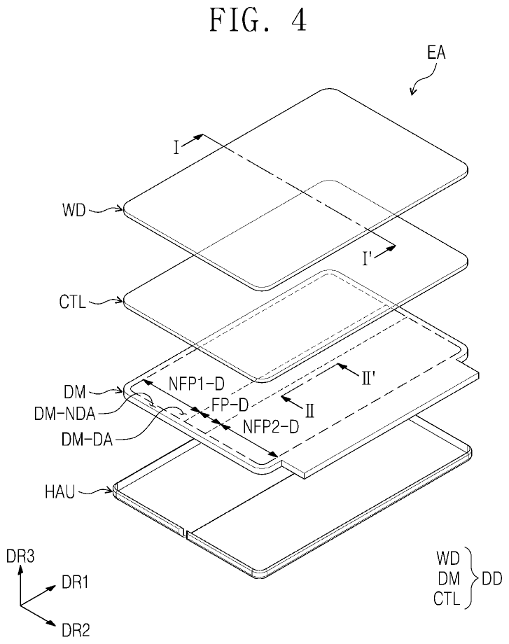

FIG. 4 is an exploded perspective view of an embodiment of the electronic apparatus EA of the disclosure. Referring to FIG. 4, the electronic apparatus EA may include a display device DD. The display device DD may include the display module DM, a window WD disposed on the display module DM, and a coating layer CTL disposed between the display module DM and the window WD. In addition, the electronic apparatus EA may further include a housing HAU disposed under the display module DM.

The window WD may be folded with respect to at least one folding axis FX1 or FX2 (refer to FIG. 3B or 3D). The window WD disposed on the coating layer CTL may be easily and repeatedly folded and unfolded and may have improved impact resistance and excellent reliability. Accordingly, the electronic apparatus EA including the coating layer CTL and the window WD may have excellent reliability and superior display quality.

The image IM (refer to FIG. 3A) generated by the display module DM may be provided to the user after passing through the window WD. The display module DM may display the image in response to electrical signals and may transmit and receive information about the external input. The display module DM may include a display area DM-DA and a non-display area DM-NDA.

The display area DM-DA may be defined as an area from which the image provided by the display module DM is emitted. The display area DM-DA of the display module DM may correspond to at least a portion of the first active area F-AA (refer to FIG. 3A).

Driving circuits or driving lines to drive the display area DM-DA may be arranged in the non-display area DM-NDA. The non-display area DM-NDA may be defined next (adjacent) to the display area DM-DA. In an embodiment, the non-display area DM-NDA may surround the display area DM-DA, however, this is merely one of embodiments. In an embodiment, the non-display area DM-NDA may be defined in various shapes, and should not be particularly limited.

The display module DM may be folded with respect to the folding axes FX1 and FX2 (refer to FIGS. 3B and 3D). The display module DM may include a folding display part FP-D and non-folding display parts NFP1-D and NFP2-D. The folding display part FP-D may correspond to the folding area FA (refer to FIG. 3A), and the non-folding display parts NFP1-D and NFP2-D may correspond to the non-folding areas NFA1 and NFA2 (refer to FIG. 3A). In the disclosure, a folding part of the display module DM may be also referred to as the folding display part FP-D, and first and second non-folding parts of the display module DM may be defined as the first and second non-folding display parts NFP1-D and NFP2-D, respectively.

The folding display part FP-D may correspond to a portion folded with respect to the folding axes FX1 and FX2 (refer to FIGS. 3B and 3D). The non-folding display parts NFP1-D and NFP2-D may include a first non-folding display part NFP1-D and a second non-folding display part NFP2-D. The folding display part FP-D may be disposed between the first non-folding display part NFP1-D and the second non-folding display part NFP2-D in the second direction DR2. The first non-folding display part NFP1-D may be next (adjacent) to one side of the folding display part FP-D, and the second non-folding display part NFP2-D may be next (adjacent) to an opposite side of the folding display part FP-D. The first non-folding display part NFP1-D may be disposed next (adjacent) to the one side of the folding display part FP-D in the second direction DR2, and the second non-folding display part NFP2-D may be disposed next (adjacent) to an opposite side of the folding display part FP-D in the second direction DR2. The first non-folding display part NFP1-D may correspond to the first non-folding area NFA1 (refer to FIG. 3A). The second non-folding display part NFP2-D may correspond to the second non-folding area NFA2 (refer to FIG. 3A).

The housing HAU may include a material with relatively high rigidity. In an embodiment, the housing HAU may include a plurality of frames and/or plates including of a glass, plastic, or metal material. The housing HAU may provide an accommodation space. The display module DM may be accommodated in the accommodation space and may be protected from external impacts.

FIG. 5 is a cross-sectional view taken along line I-I′ of FIG. 4. FIG. 5 is a cross-sectional view showing the electronic apparatus EA. In FIG. 5, for convenience of explanation, the housing HAU (refer to FIG. 4) is omitted.

Referring to FIG. 5, the electronic apparatus EA may further include a protective layer PL, a lower module LM, a lower adhesive layer AP-D, and a lower protective film DF. The protective layer PL may be disposed on the display device DD. The lower module LM, the lower adhesive layer AP-D, and the lower protective film DF may be disposed between the display module DM and the housing HAU (refer to FIG. 4).

The lower module LM may be disposed under the display module DM. The lower module LM may include a support plate MP and a lower support member BSM. The configuration of the lower module LM shown in FIG. 5 is an example, and a combination of components included in the lower module LM in the electronic apparatus EA may vary depending on the size of the electronic apparatus EA, the shape of the electronic apparatus EA, or operating characteristics of the electronic apparatus EA.

The support plate MP may include a metal material or a polymer material. In an embodiment, the support plate MP may include stainless steel, aluminum, or any alloys thereof. A plurality of openings OP may be defined through the support plate MP. The support plate MP may define an opening pattern OP-PT through which the openings OP are defined. The opening pattern OP-PT may be formed in the folding area FA.

The lower support member BSM may include a support member SPM and a filling portion SAP. In a plan view, the support member SPM may overlap with most of the portion of the display module DM. The filling portion SAP may be disposed outside the support member SPM and may overlap with an outer periphery of the display module DM.

The support member SPM may include at least one of a support layer SP, a cushion layer CP, a shielding layer EMP, and an inter-adhesive layer ILP. The configuration of the support member SPM shown in FIG. 5 is merely one of embodiments, and the disclosure should not be limited to that shown in FIG. 5. In an embodiment, one or more of the support layer SP, the cushion layer CP, the shielding layer EMP, and the inter-adhesive layer ILP may be omitted, their stacking order may be changed to an order different from that in FIG. 5, or an additional component other than the illustrated components may be further added in the support member SPM.

The support layer SP may include a metal material or a polymer material. The support layer SP may be disposed under the support plate MP. In an embodiment, the support layer SP may be a thin metal substrate. The support layer SP may include a first sub-support layer SP1 and a second sub-support layer SP2 spaced apart from the first sub-support layer SP1 in the second direction DR2. The first sub-support layer SP1 and the second sub-support layer SP2 may be spaced apart from each other in an area corresponding to the folding axes FX1 and FX2 (refer to FIGS. 3B and 3D). As the support layer SP includes the first sub-support layer SP1 and the second sub-support layer SP2 that are spaced apart from each other in the folding area FA, folding characteristics of the electronic apparatus EA may be improved.

The cushion layer CP may be disposed under the support layer SP. The cushion layer CP may prevent the support plate MP from being pressed and plastic-deformed due to external impacts and forces. The cushion layer CP may improve the impact resistance of the electronic apparatus EA. The cushion layer CP may include a sponge, a foam, or an elastomer such as a urethane resin. In addition, the cushion layer CP may include at least one of an acrylic-based polymer, a urethane-based polymer, a silicone-based polymer, and an imide-based polymer, however, it should not be limited thereto or thereby.

The cushion layer CP may include a first sub-cushion layer CP1 and a second sub-cushion layer CP2 spaced apart from the first sub-cushion layer CP1 in the second direction DR2. The first sub-cushion layer CP1 and the second sub-cushion layer CP2 may be spaced apart from each other in an area corresponding to the folding axes FX1 and FX2 (refer to FIGS. 3B and 3D). As the cushion layer CP includes the first sub-cushion layer CP1 and the second sub-cushion layer CP2 that are spaced apart from each other in the folding area FA, the folding characteristics of the electronic apparatus EA may be improved.

The shielding layer EMP may be an electromagnetic shielding layer or a heat dissipation layer. In addition, the shielding layer EMP may perform a function of an adhesive layer.

The inter-adhesive layer ILP may attach the support plate MP to the support member SPM. The inter-adhesive layer ILP may be provided in the form of an adhesive resin layer or an adhesive tape. FIG. 5 shows a structure in which the inter-adhesive layer ILP is divided into two portions spaced apart from each other in an area corresponding to the folding axes FX1 and FX2 (refer to FIGS. 3B and 3D), however, the disclosure should not be limited thereto or thereby. The inter-adhesive layer ILP may be provided as a single layer without being divided into portions in the area corresponding to the folding axes FX1 and FX2 (refer to FIGS. 3B and 3D).

The filling portion SAP may be disposed outside the support layer SP and the cushion layer CP. The filling portion SAP may be disposed between the support plate MP and the housing HAU (refer to FIG. 4). The filling portion SAP may be filled in a space between the support plate MP and the housing HAU (refer to FIG. 4) and may fix the support plate MP.

The lower protective film DF may be disposed between the display module DM and the support plate MP. The lower protective film DF may be disposed under the display module DM and may protect a rear surface of the display module DM. The lower protective film DF may cover an entirety of with the display module DM. The lower protective film DF may include a polymer material. In an embodiment, the lower protective film DF may be a polyimide film or a polyethylene terephthalate film, however, this is merely one of embodiments, and the lower protective film DF should not be limited thereto or thereby.

The lower adhesive layer AP-D may be disposed between the support plate MP and the lower protective film DF. The support plate MP and the lower protective film DF may be coupled with each other by the lower adhesive layer AP-D. The lower adhesive layer AP-D may include a pressure sensitive adhesive (“PSA”), an optically clear adhesive (“OCA”) film, or an optically clear adhesive resin (“OCR”) layer, however, the disclosure should not be limited thereto or thereby. In an embodiment, the lower adhesive layer AP-D may be omitted.

The display module DM may include a display panel DP and an input sensing part TP disposed on the display panel DP. The display panel DP may substantially generate images. The display panel DP may be folded with respect to the folding axes FX1 and FX2 (refer to FIGS. 3B and 3D).

The input sensing part TP may be disposed on the display panel DP. The input sensing part TP may sense an external input, may convert the sensed input to an input signal, and may provide the input signal to the display panel DP. In an embodiment, the input sensing part TP may be a touch sensing part that senses a touch event. The input sensing part TP may sense a user's direct touch, a user's indirect touch, an object's direct touch, or an object's indirect touch.

The input sensing part TP may sense at least one of a position of a touch event applied from the outside and an intensity (pressure) of the touch event applied from the outside. The input sensing part TP may have various structures or may include various materials, and it should not be particularly limited. In an embodiment, the input sensing part TP may sense the external input in a capacitive manner. The display panel DP may receive the input signal from the input sensing part TP and may generate the image corresponding to the input signal.

The protective layer PL may be disposed on the window WD. The protective layer PL may be a functional layer that protects one surface e.g., an upper surface, of the window WD. In an embodiment, the protective layer PL may include polyethylene terephthalate (“PET”). The protective layer PL may also include an anti-fingerprint coating agent, an anti-static agent, a hard coating agent, or the like.

In an embodiment, the electronic apparatus EA may not include a damping layer and adhesive layers disposed above and below the damping layer. The electronic apparatus EA in which the window WD is disposed on the coating layer CTL may have a thin thickness because the electronic apparatus EA does not include the damping layer and the adhesive layer.

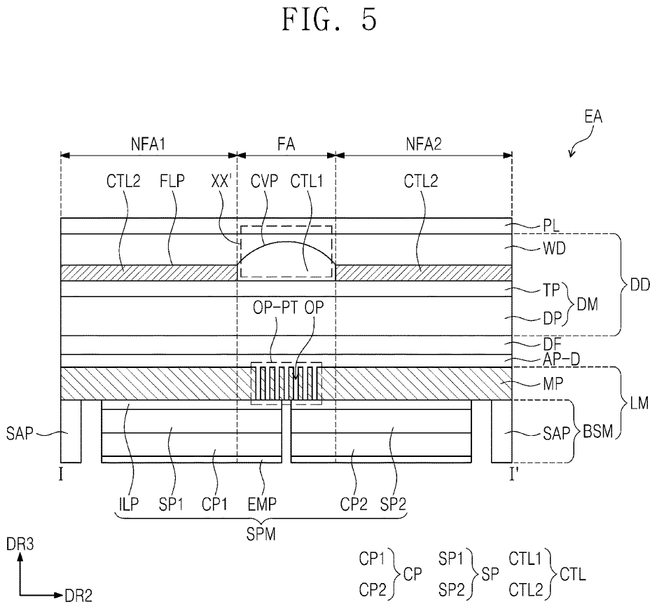

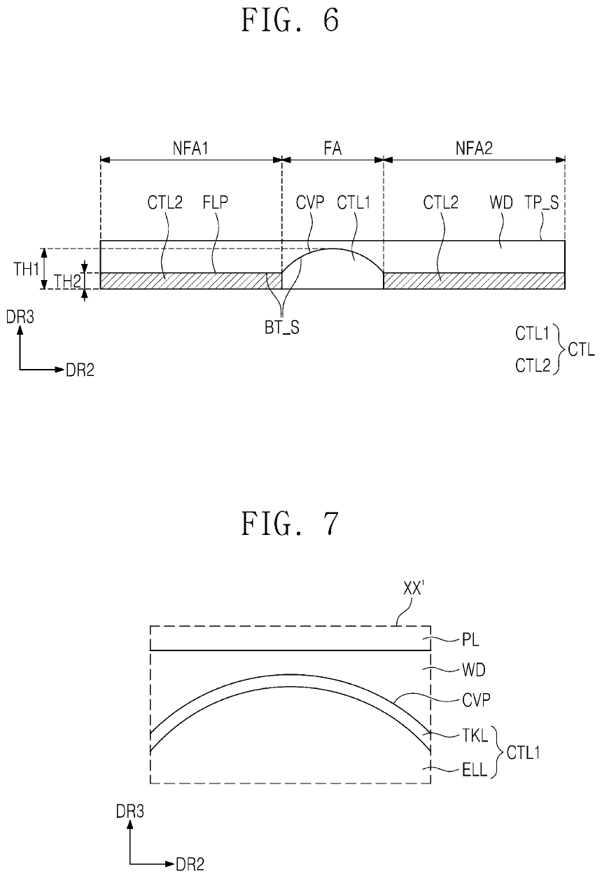

FIG. 6 is a cross-sectional view showing an embodiment of the window WD and the coating layer CTL included in the electronic apparatus EA (refer to FIG. 5) of the disclosure. The window WD may be a glass substrate. In an embodiment, the window WD may be a tempered glass substrate that has undergone a strengthening process, for example. The window WD may include an ultra-thin glass (“UTG”). The window WD may be repeatedly folded and unfolded. The window WD may include a concave portion CVP overlapping the folding area FA of the electronic apparatus EA (refer to FIG. 5). The window WD may include a flat portion FLP overlapping the non-folding areas NFA1 and NFA2 of the electronic apparatus EA (refer to FIG. 5). The concave portion CVP may overlap the folding display part FP-D (refer to FIG. 4) of the display module DM (refer to FIG. 4). The flat portion FLP may overlap the non-folding display parts NFP1-D and NFP2-D (refer to FIG. 4) of the display module DM (refer to FIG. 4). The window WD may include a top surface TP_S and a bottom surface BT_S disposed between the top surface TP_S and the display module DM (refer to FIG. 5). The concave portion CVP and the flat portion FLP may be included in the bottom surface BT_S of the window WD. The top surface TP_S of the window WD may be flat. The window WD including the flat top surface TP_S may have improved surface quality. The bottom surface BT_S of the window WD including the concave portion CVP and the flat portion FLP may not be flat. Accordingly, the window WD may have a non-uniform thickness.

The window WD including the concave portion CVP and the flat portion FLP may exhibit excellent reliability when being folded. The concave portion CVP may be concave downward and may be thinner than the flat portion FLP. Accordingly, the electronic apparatus EA (refer to FIGS. 3A to 3D) including the concave portion CVP and the flat portion FLP may be easily folded.

The coating layer CTL may be disposed between the display module DM (referring to FIG. 5) and the window WD. The electronic apparatus EA (referring to FIGS. 3A to 3D), in which the window WD having the flat top surface TP_S is disposed on the coating layer CTL, may have excellent display quality. The coating layer CTL may include a first coating layer CTL1 that contacts the concave portion CVP and a second coating layer CTL2 that contacts the flat portion FLP. The first coating layer CTL1 and the second coating layer CTL2 may have different moduli. The first coating layer CTL1 and the second coating layer CTL2 may be integrally formed (or unitary) with each other. The window WD disposed on the coating layer CTL, which includes the first coating layer CTL1 and the second coating layer CTL2, may have improved impact resistance and excellent folding reliability. Accordingly, the electronic apparatus EA (referring to FIGS. 3A to 3D) may have excellent reliability and superior display quality.

The first coating layer CTL1 may overlap the folding area FA. The second coating layer CTL2 may overlap the non-folding areas NFA1 and NFA2. The first coating layer CTL1 may overlap the folding display part FP-D (refer to FIG. 4) of the display module DM (refer to FIG. 4). The second coating layer CTL2 may overlap the non-folding display parts NFP1-D and NFP2-D (refer to FIG. 4) of the display module DM (refer to FIG. 4). The first coating layer CTL1 may not overlap the non-folding areas NFA1 and NFA2, and the second coating layer may not overlap the folding area FA.

The first coating layer CTL1 may have a thickness TH1 greater than or equal to about 60 micrometers (μm) and smaller than or equal to about 120 μm. The second coating layer CTL2 may have a thickness TH2 greater than or equal to about 10 μm and smaller than or equal to about 30 μm. The thickness TH1 of the first coating layer CTL1 may be greater than the thickness TH2 of the second coating layer CTL2. In an embodiment, the thickness TH1 of the first coating layer CTL1 may be about 100 μm, and the thickness TH2 of the second coating layer CTL2 may be about 20 μm. When the thickness of the first coating layer is greater than about 120 μm, the thickness of the electronic apparatus may increase. When the thickness of the first coating layer is smaller than about 60 μm, the impact resistance of the first coating layer may decrease. When the thickness of the second coating layer is greater than about 30 μm, the thickness of the electronic apparatus may increase. When the thickness of the second coating layer is smaller than about 10 μm, the impact resistance of the second coating layer may decrease.

The coating layer CTL may have the same thickness as the thickness TH1 of the first coating layer CTL1. The thickness of the coating layer CTL may vary depending on the thickness TH1 of the first coating layer CTL1. Therefore, a sum of the thickness of the coating layer CTL and the thickness of the window WD may vary.

A sum of the thickness of the concave portion CVP and the thickness TH1 of the first coating layer CTL1 may be equal to a sum of the thickness of the flat portion FLP and the thickness TH2 of the second coating layer CTL2. Accordingly, the top surface TP_S of the member including the coating layer CTL and the window WD may be flat. A thickness obtained by subtracting the thickness TH2 of the second coating layer CTL2 from the thickness TH1 of the first coating layer CTL1 may be the same as a depth of the concave portion CVP in the third directional axis (also referred to as a third direction) DR3.

The first coating layer CTL 1 may have a storage modulus smaller than or equal to about 0.1 megapascal (MPa) at room temperature. The second coating layer CTL2 may have a tensile modulus greater than or equal to about 1 MPa and smaller than or equal to about 100 MPa at room temperature. The room temperature may refer to a temperature greater than or equal to about 15 degrees Celsius (°C) and smaller than or equal to about 25 °C.

The first coating layer CTL1, which contacts the concave portion CVP of the window WD and has the storage modulus smaller than or equal to about 0.1 MPa, may have excellent flexibility and relatively high adhesion and may absorb external impacts. The second coating layer CTL2, which contacts the flat portion FLP of the window WD and has the tensile modulus greater than or equal to about 1 MPa and smaller than or equal to about 100 MPa, may prevent deformation of the window WD and may relieve stress generated during the folding operation. Accordingly, the electronic apparatus EA (referring to FIGS. 3A to 3D), which includes the first coating layer CTL1 having the storage modulus smaller than or equal to about 0.1 MPa and the second coating layer CTL2 having the tensile modulus greater than or equal to about 1 MPa and smaller than or equal to about 100 MPa, may have excellent folding reliability and excellent impact resistance.

A difference between a refractive index of the window WD and a refractive index of the coating layer CTL may be smaller than or equal to about 0.2. When the difference in refractive index is smaller than or equal to about 0.2, an interface between the window WD and the coating layer CTL may not be visible. When the difference between the refractive index of the window and the refractive index of the coating layer exceeds about 0.2, the interface between the window and the coating layer may be visible. When the interface between the window and the coating layer is visible, the transmittance of the window may decrease, and the display quality of the electronic apparatus may be degraded. In contrast, the electronic apparatus EA (referring to FIGS. 3A to 3D) in which the difference between the refractive index of the window WD and the refractive index of the coating layer CTL is smaller than about 0.2 may have excellent display quality.

A creep measured 1 hour after a manufacturing time point of the coating layer CTL may be greater than or equal to 0.05 times and smaller than or equal to 0.2 times of a creep measured at the manufacturing time point of the coating layer CTL. The coating layer CTL whose creep measured 1 hour after the manufacturing time point is greater than or equal to 0.05 times and smaller than or equal to 0.2 times of the creep measured at the manufacturing time point shows little deformation even after 1 hour under a predetermined force. Accordingly, the electronic apparatus EA (referring to FIGS. 3A to 3D) including the coating layer CTL may have excellent folding reliability as wrinkles do not form in the folding area FA.

Further, the coating layer CTL may have a recovery rate greater than or equal to about 90% after undergoing 100 cycles of tensile tests. A coating layer with a recovery rate smaller than about 90% after 100 cycles of tensile tests has a relatively low rate of returning to its original shape after being subjected to a constant force, and accordingly, wrinkles may form in the electronic apparatus during repeated folding and unfolding operations. In contrast, the electronic apparatus EA (referring to FIGS. 3A to 3D) including the coating layer CTL with a recovery rate greater than or equal to about 90% after undergoing 100 cycles of tensile tests may have excellent folding reliability as wrinkles do not form in the folding area FA even with repeated folding and unfolding operations.

FIG. 7 is an enlarged view of an area XX′ of FIG. 5. FIG. 7 shows the first coating layer CTL1 in detail.

The first coating layer CTL1 may include a tackifier layer TKL and an elastic layer ELL disposed under the tackifier layer TKL. The tackifier layer TKL may contact the concave portion CVP of the window WD, and the elastic layer ELL may be disposed between the tackifier layer TKL and the display module DM (refer to FIG. 5). In an embodiment, the elastic layer ELL may contact the tackifier layer TKL.

The tackifier layer TKL may include or consist of an oligomer including an alkyl group having 5 carbon atoms to 20 carbon atoms. The alkyl group may be included in a side chain of the oligomer. The oligomer may be a tackifier.

The oligomer may have a glass transition temperature (Tg) greater than or equal to 80 °C and smaller than or equal to 120 °C. The tackifier layer formed from an oligomer with a glass transition temperature below 80 °C may have relatively low tolerance under relatively high temperature and relatively high humidity environments, causing a decrease in adhesive strength of the tackifier layer. In contrast, the tackifier layer TKL formed from the oligomer with the glass transition temperature of 80 °C or higher may maintain a constant adhesive strength without degradation of its tolerance even in relatively high temperature and relatively high humidity environments. The tackifier layer formed from an oligomer with a glass transition temperature exceeding 120 °C may have relatively low adhesive strength because the cohesiveness of the polymer constituting the tackifier layer is substantially high. In contrast, the tackifier layer TKL formed from the oligomer with the glass transition temperature of 120 °C or lower may have excellent cohesiveness of the polymer constituting the tackifier layer TKL and may have excellent adhesive strength.

The tackifier layer TKL, which is formed from the oligomer including the alkyl group having 5 carbon atoms to 20 carbon atoms, may not be delaminated under high-temperature and high-humidity conditions (e.g., a temperature of about 60 °C and a relative humidity of about 93%), and thus, the tackifier layer TKL may have excellent adhesion reliability. Accordingly, the electronic apparatus EA (refer to FIGS. 3A to 3D) including the tackifier layer TKL may have excellent reliability.

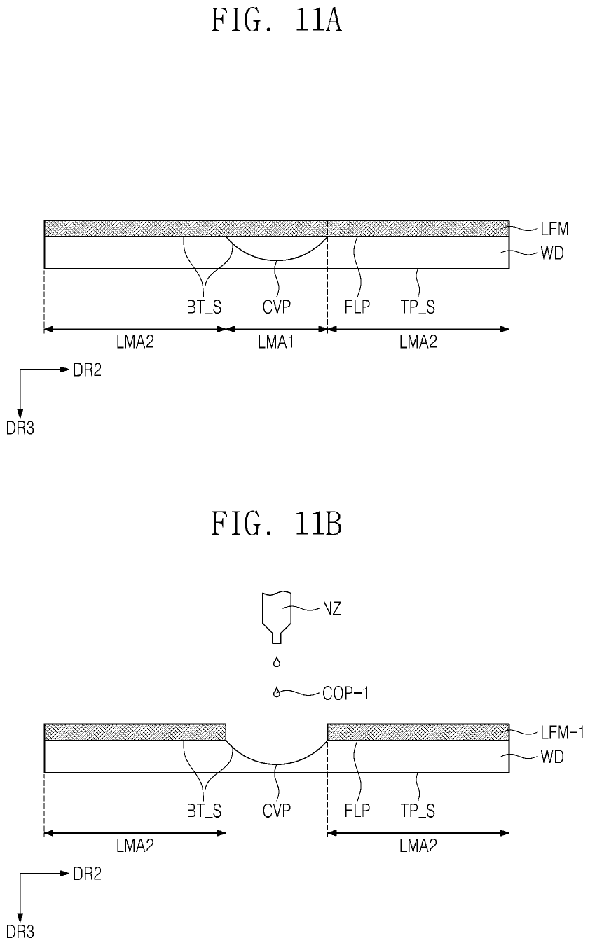

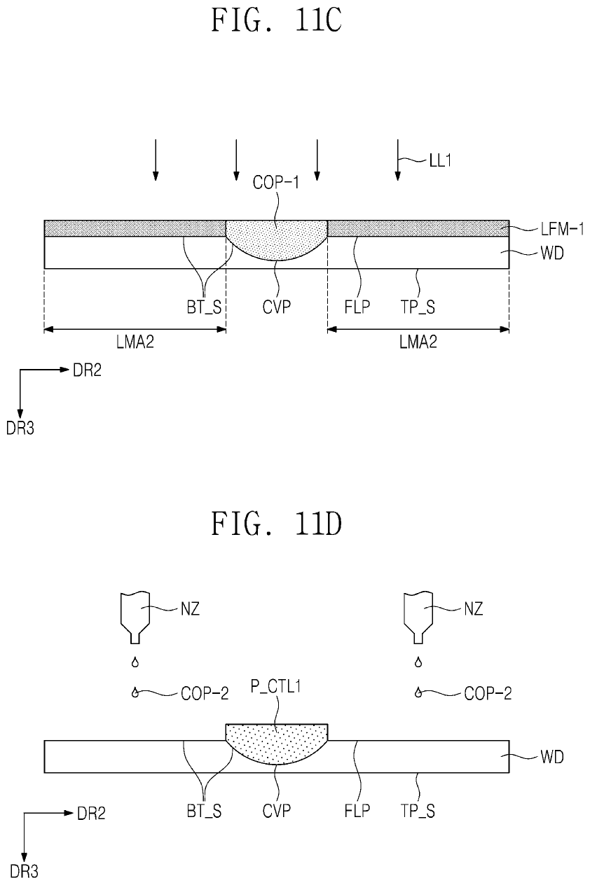

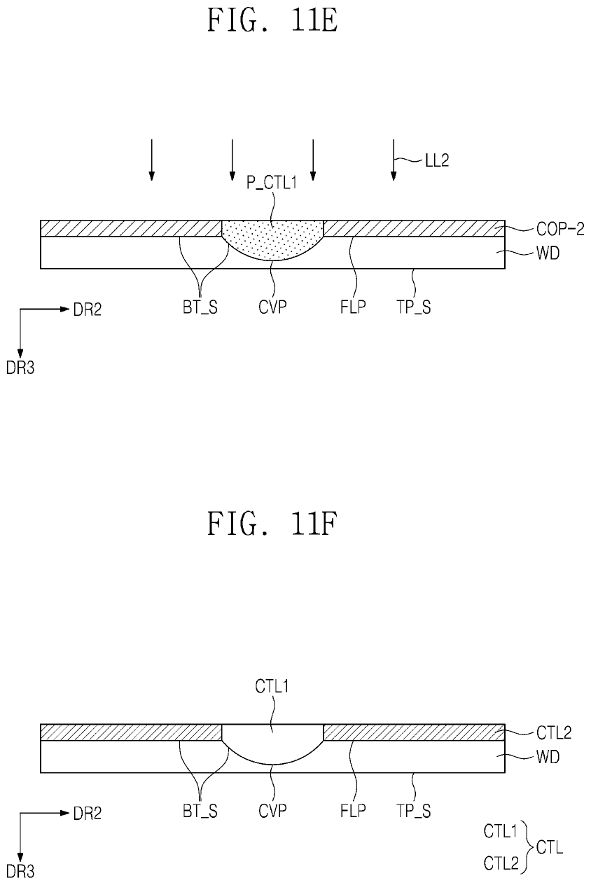

The oligomer that forms the tackifier layer TKL may be provided by being dispersed in a first resin composition COP-1 (refer to FIG. 11B) that forms the first coating layer CTL1. The process of forming the tackifier layer TKL will be described in more detail later.

Tables 1 and 2 below present evaluation results of the coating layers of the experimental examples. In detail, Table 1 illustrates an evaluation result of the physical properties when the coating layer has a single structure. Table 2 illustrates an evaluation result of the physical properties when the coating layer has a composite structure including the first coating layer and the second coating layer.

The coating layers of experimental examples 1-1 to 1-3 in Table 1 may be used as the first coating layer. The coating layers of experimental examples 2-1 to 2-4 in Table 1 may be used as the second coating layer. In Tables, “experimental example” is referred to as “EE” for convenience.

In the forming of the coating layers of the experimental examples, at least one of an acrylic resin, a urethane resin, and a silicone resin was used. When forming the coating layers of the experimental examples, the coating layers having target physical properties were fabricated by adjusting a crosslink density of a resin composition used in the forming of the coating layer or by adjusting a combination of monomers and/or oligomers.

In Tables 1 and 2, the storage modulus of experimental examples 1-1 to 1-3 at room temperature (RT) was measured and presented using a Rheometer. The tensile modulus of experimental examples 2-1 to 2-4 at room temperature was measured and presented using a tensile mode of a universal testing machine (“UTM”)/force testing machine (“FTM”) instrument.

In Tables 1 and 2, a strain (cy) of the coating layers of the experimental examples at room temperature was measured and presented using the tensile mode of the UTM/FTM instrument. The strain of the coating layers of the experimental examples were set to be less than about 2.5% to maintain a stable recovery force after being subjected to deformation such as folding.

In Tables 1 and 2, the recovery rate after 100 cycles of tensile tests repeatedly performed on the coating layers of the experimental examples at room temperature was measured and presented using the tensile mode of the UTM/FTM instrument. The creep strain of the coating layers of the experimental examples at room temperature over 1 hour was measured and presented using the tensile mode of the UTM/FTM instrument. In addition, the adhesion of the coating layers of the experimental examples at room temperature was measured and presented.

In Table 1, the adhesion of the coating layers of the experimental examples was measured and presented under conditions of the temperature of about 60 °C and the relative humidity of about 93%. In Table 1, “w/TKL” denotes that the coating layer includes the tackifier layer. When the tackifier layer was included in the coating layers of the experimental examples, the adhesion at room temperature was measured and presented. Further, when the tackifier layer was included in the coating layers of the experimental examples, the adhesion under conditions of the temperature of about 60 °C and the relative humidity of about 93% was measured and presented. The tackifier layer is formed from the oligomer including the alkyl group having 5 carbon atoms to 20 carbon atoms as the side chain.

TABLE 1

| | Single structure | | | | | | |
|---|---|---|---|---|---|---|---|
| | EE 1-1 | EE 1-2 | EE 1-3 | EE 2-1 | EE 2-2 | EE 2-3 | EE 2-4 |
| Modulus | 0.1 | 0.06 | 0.04 | 50 | 100 | 160 | 230 |
| (MPa) | | | | | | | |
| εγ (%) | 1.9 | 2.1 | 2.1 | 2 | 2.2 | 1.9 | 2 |
| Recovery | 93 | 95 | 90 | 85 | 92 | 90 | 95 |
| rate (%) | | | | | | | |
| Creep (%) | 12 | 2 | 0 | 80 | 43 | 30 | 22 |
| Adhesion | 500 | 700 | 800 | 1200 | 1000 | 1500 | 1800 |
| (gf) | | | | | | | |
| Adhesion | 100 | 180 | 300 | — | | | |
| (gf, | | | | | | | |
| 60 °C/93%) | | | | | | | |
| Adhesion | 700 | 1000 | 1200 | | | | |
| (w/TKL gf, | | | | | | | |
| RT) | | | | | | | |
| Adhesion | 300 | 420 | 650 | | | | |
| (w/TKL gf, | | | | | | | |
| 60 °C/93%) | | | | | | | |

Referring to Table 1, it is observed that the coating layers of experimental examples 1-1 to 1-3 exhibit relatively low adhesion under the high-temperature and high-humidity conditions (e.g., the temperature of about 60 °C and the relative humidity of about 93%) when the coating layers do not include the tackifier layer. In contrast, when the coating layers of experimental examples 1-1 to 1-3 include the tackifier layer, the coating layers exhibit relatively high adhesion under the high-temperature and high-humidity conditions. From this, it is understood that the first coating layer including the tackifier layer has the relatively high adhesion under the high-temperature and high-humidity conditions.

In Table 2, the folding reliability of the electronic apparatus including the coating layers of the experimental examples was evaluated by in-folding the electronic apparatus with a radius of curvature of about 2 mm. When the coating layer is delaminated, it was evaluated as ‘NG’, and when the coating layer is not delaminated and the adhesion is maintained, it was evaluated and recorded as ‘OK’. The folding reliability was evaluated under room temperature (RT) and relatively high temperature/high humidity (HT) conditions.

In Table 2, the impact resistance of the electronic apparatus including the coating layer of the experimental example was evaluated using a pen drop test. The maximum height (cm) at which a pen with a predetermined weight and shape, when dropped vertically onto the front surface of the electronic apparatus, did not cause damage due to the drop impact was measured and recorded.

In Table 2 below, experimental example A uses the coating layer of experimental example 1-1 in Table 1 as the first coating layer and the coating layer of experimental example 2-1 in Table 1 as the second coating layer. Experimental examples B1 and B2 use the coating layer of experimental example 1-2 in Table 1 as the first coating layer, experimental example B1 uses the coating layer of experimental example 2-3 in Table 1 as the second coating layer, and experimental example B2 uses the coating layer of experimental example 2-4 in Table 1 as the second coating layer. Experimental Examples C1 to C4 use the coating layer of experimental example 1-3 in Table 1 as the first coating layer, experimental example C1 uses the coating layer of experimental example 2-1 in Table 1 as the second coating layer, experimental example C2 uses the coating layer of experimental example 2-2 in Table 1 as the second coating layer, experimental example C3 uses the coating layer of experimental example 2-3 in Table 1 as the second coating layer, and experimental example C4 uses the coating layer of experimental example 2-4 in Table 1 as the second coating layer.

TABLE 2

| | Composite structure | | | | | | |
|---|---|---|---|---|---|---|---|
| coating | EE A | EE B1 | EE B2 | EE C1 | EE C2 | EE C3 | EE C4 |
| layer | | | | | | | |
| first coating | EE 1-1 | EE 1-2 | EE 1-2 | EE 1-3 | EE 1-3 | EE 1-3 | EE 1-3 |
| layer | | | | | | | |
| second | EE 2-1 | EE 2-3 | EE 2-4 | EE 2-1 | EE 2-2 | EE 2-3 | EE 2-4 |
| coating | | | | | | | |
| layer | | | | | | | |
| Modulus | 38 | 130 | 205 | 40 | 82 | 116 | 200 |
| (MPa) | | | | | | | |
| εγ (%) | 2 | 1.9 | 2.1 | 2.1 | 2 | 1.9 | 2.2 |
| Recovery | 87 | 90 | 92 | 92 | 93 | 91 | 93 |
| rate (%) | | | | | | | |
| Creep (%) | 25 | 22 | 19 | 18 | 15 | 11 | 10 |
| Adhesion | 1100 | 1400 | 1600 | 1200 | 1100 | 1500 | 1700 |
| (gf, RT) | | | | | | | |

electronic apparatus

| | | | | | | | |
|---|---|---|---|---|---|---|---|
| Folding | NG | NG | NG | OK (RT) | OK (RT) | NG | NG |
| reliability | | | | NG (HT) | NG (HT) | | |
| Impact | 2 | 6 | 8 | 7 | 9 | 8 | 9 |
| resistance | | | | | | | |

Referring to Table 2, it is observed that the electronic apparatus including the coating layers of experimental examples C1 and C2 has excellent folding reliability and excellent impact resistance at room temperature. In experimental examples C1 and C2, the coating layer of experimental example 1-3 in Table 1 is used as the first coating layer. Based on this, it is understood that it is suitable for the storage modulus of the first coating layer to be 0.1 MPa or less. In experimental examples C1 and C2, the coating layers of experimental examples 2-1 and 2-2 in Table 1 are used as the second coating layer. Based on this, it is understood that it is suitable for the tensile modulus of the second coating layer to be 1 MPa or more and 100 MPa or less.

Referring to the coating layers of experimental examples C1 and C2, the creep measured 1 hour after the manufacturing time point of the coating layer is 0.05 times to 0.2 times the creep measured at the manufacturing time point of the coating layer. Based on this, it is observed that the coating layer where the creep measured 1 hour after the manufacturing time point is 0.05 times to 0.2 times the creep measured at the manufacturing time point has excellent folding reliability and excellent impact resistance at room temperature. The coating layers of experimental examples C1 and C2 have the recovery rate greater than or equal to 90% after the tensile test is performed 100 times. From this, it is observed that the coating layers with the recovery rate greater than or equal to 90% after 100 cycles of tensile tests exhibit excellent folding reliability and excellent impact resistance at room temperature.

In contrast, the coating layers of experimental examples A, B1, B2, C3, and C4 exhibit relatively high modulus, relatively low recovery rate, and/or relatively high creep. This leads to an imbalance in the tensile stress and compressive stress between the first coating layer and the second coating layer, resulting in reduced folding reliability and/or impact resistance of the electronic apparatus including the coating layers of experimental examples A, B1, B2, C3, and C4.

In Table 3 below, electronic apparatuses of experimental examples C1-1 to C4-1 are those where the tackifier layer is added to the coating layers of experimental examples C1 to C4 in Table 2. The tackifier layer is included in the first coating layer. The tackifier layer is formed from the oligomer including the alkyl group having 5 carbon atoms to 20 carbon atoms. The electronic apparatuses of experimental examples C1-1 to C4-1 were evaluated in the same manner as the evaluation of the electronic apparatuses including the coating layers of the experimental examples in Table 2.

TABLE 3

| | Composite structure | | | |
|---|---|---|---|---|
| electronic | EE | EE | EE | EE |
| apparatus | C1-1 | C2-1 | C3-1 | C4-1 |
| Folding | OK (RT) | OK (RT) | NG | NG |
| reliability | OK (HT) | OK (HT) | | |
| Impact | 7 | 9 | 8 | 10 |
| resistance | | | | |

Referring to Tables 2 and 3, it is observed that the electronic apparatuses of experimental example C1-1 and experimental example C2-1 have excellent folding reliability at both room temperature and relatively high temperatures. Accordingly, it is understood that the coating layer having the composite structure and including the tackifier layer has relatively high adhesion under high-temperature and high-humidity conditions, and the electronic apparatus including the coating layer has excellent folding reliability at both room temperature and relatively high temperatures.

In contrast, the electronic apparatuses of experimental examples C3-1 and C4-1 include the coating layers with a relatively high modulus, relatively low recovery rate, and/or relatively high creep. As a result, even when the tackifier layer is included in the coating layer, the imbalance occurs in the tensile stress and compressive stress between the first coating layer and the second coating layer, and the folding reliability of the electronic apparatus is degraded.

Table 4 below illustrates an evaluation result of the dispersion force of the resin compositions and the window used when manufacturing the electronic apparatuses of experimental examples C1-1 and C2-1 in Table 3. In detail, the resin composition of Resin_C was used in the manufacturing of the first coating layer in the electronic apparatuses of experimental examples C1-1 and C2-1. The resin composition of Resin_a was used in the manufacturing of the second coating layer in the electronic apparatus of experimental example C1-1. The resin composition of Resin_b was used in the manufacturing of the second coating layer in the electronic apparatus of experimental example C2-1. In the disclosure, the resin composition used in the manufacturing of the first coating layer is defined as the first resin composition, and the resin composition used in the manufacturing of the second coating layer is defined as a second resin composition.

In Table 4, a non-polar dispersion force (γd), a polar dispersion force (γp), and a total dispersion force (γtotal), which is a sum of the non-polar and the polar dispersion forces, of the resin composition and the window were measured and recorded. The total dispersion force (γtotal), which is the sum of the non-polar and polar dispersion forces, is equal to a surface tension (γSV) between the window and vapor and a surface tension (γLV) between the resin composition and vapor.

The difference (Δγd) in non-polar dispersion force between the window and the resin composition was measured and recorded. In addition, an interfacial tension (γSL) between the window and the resin composition was measured and recorded.

TABLE 4

| | | γd (mN/m) | γp (mN/m) | γtotal (mN/m) | Δγd | γSL (mN/m) |
|---|---|---|---|---|---|---|
| resin | Resin_C | 27.1 | 0.7 | 27.8 | 8.8 | 53.8 |
| composition | Resin_a | 30.2 | 0.2 | 30.4 | 11.9 | 54.3 |
| | Resin_b | 29 | 0 | 29 | 10.7 | 54.5 |

| | | | | | |
|---|---|---|---|---|---|
| Window | 18.3 | 54.5 | 72.8 | — | — |

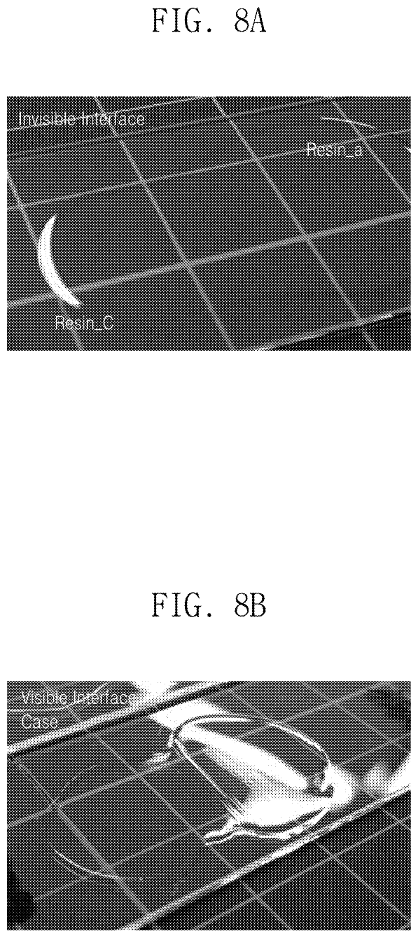

Referring to Table 4, it is observed that the difference between the dispersion force of the first resin composition and the dispersion force of the window is greater than or equal to 8 and smaller than or equal to 13, and the difference between the dispersion force of the second resin composition and the dispersion force of the window is greater than or equal to 8 and smaller than or equal to 13. In the present description, the unit of millinewtons per meter (mN/m) may be omitted when expressing the difference between the dispersion force of the first resin composition and that of the window for convenience. The resin composition with a difference in the dispersion force from the window of 8 or more and 13 or less has a surface tension similar to that of the window. Referring to FIG. 8A, it is observed that the interface between the resin composition and the window is not visible when the resin composition has the surface tension similar to that of the window. FIG. 8A is a photograph taken after providing Resin_C and Resin_a on the window. Therefore, in the case where the electronic apparatus manufactured including the first and second resin compositions having a difference in the dispersion force from the window of 8 or more and 13 or less may have excellent display quality. Further, referring to FIG. 8A, it is observed that the interface where the first resin composition contacts the second resin composition is not visible since an interfacial tension between the window and the first resin composition is similar to an interfacial tension between the window and the second resin composition.

A resin composition with a difference in dispersion force from the window exceeding 13 has a different surface tension from the window. Referring to FIG. 8B, it is observed that the interface between the window and the coating layer is visible. FIG. 8B is a photograph taken after providing two different resin compositions, each having a difference in dispersion force from the window exceeding 13, on the window. Further, referring to FIG. 8B, it is observed that the interface separates due to the difference between the interfacial tension of the window and the first resin composition and the interfacial tension of the window and the second resin composition. When the interface between the window and the resin composition and between the resin compositions themselves is visible, the transmittance of the window may be lowered, and the display quality of the electronic apparatus may be degraded.

As described above, when the coating layer, which includes the first coating layer having the storage modulus of 0.1 MPa or less and the second coating layer having the tensile modulus from 1 MPa to 100 MPa, with the first coating layer including or consisting of the tackifier layer formed from the oligomer having the alkyl group having 5 carbon atoms to 20 carbon atoms, and which exhibits the creep measured 1 hour after the manufacturing time point that is between 0.05 times and 0.2 times the creep measured at the manufacturing time point and the recovery rate of 90% or more after 100 cycles of tensile tests, is placed under the window, the coating layer may facilitate repeated folding and unfolding operations and contribute to enhanced impact resistance and excellent reliability. Further, when the difference between the dispersion force of the first resin composition forming the first coating layer and the dispersion force of the window is greater than or equal to 8 and smaller than or equal to 13 and the difference between the dispersion force of the second resin composition forming the second coating layer and the dispersion force of the window is greater than or equal to 8 and smaller than or equal to 13, the electronic apparatus manufactured including the first and second resin compositions may have excellent reliability and excellent display quality.

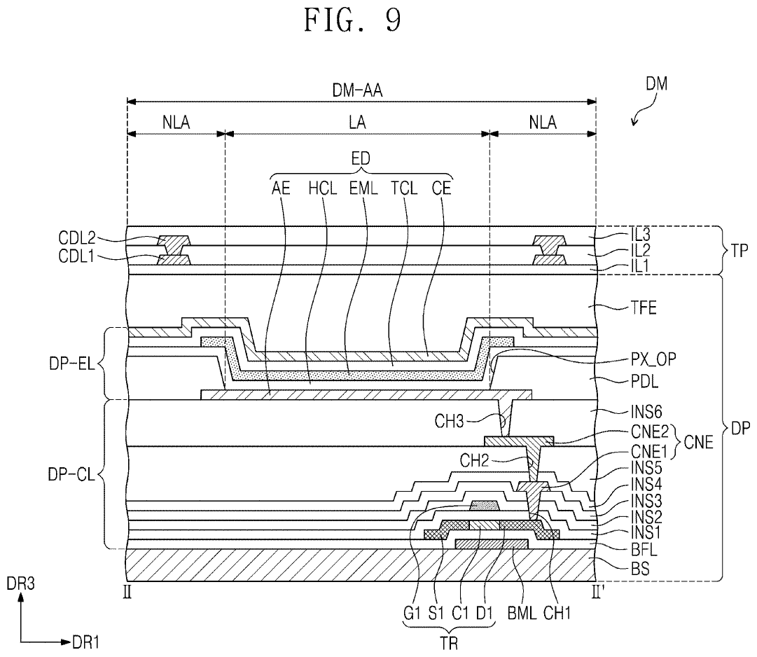

FIG. 9 is a cross-sectional view taken along line II-II′ of FIG. 4. FIG. 9 is a cross-sectional view showing an embodiment of an active area DM-DA of the display module DM of the disclosure. The display module DM shown in FIG. 9 is merely one of embodiments, and the disclosure should not be limited thereto or thereby.

A base substrate BS may have a single-layer or multi-layer structure. In an embodiment, the base substrate BS may include a first synthetic resin layer, an inorganic layer having a single-layer or multi-layer structure, and a second synthetic resin layer disposed on the inorganic layer having a single-layer or multi-layer structure. Each of the first and second synthetic resin layers may include a polyimide-based resin. In addition, each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In the disclosure, the term “A-based resin” means that a functional group of “A” is included.

The display panel DP may include a transistor TR and a light-emitting element ED. The transistor TR and the light-emitting element ED may be disposed on the base substrate BS. In an embodiment, one transistor TR is shown in FIG. 9, however, the display panel DP may include a plurality of transistors and at least one capacitor to drive the light-emitting element ED.

A circuit layer DP-CL may be disposed on the base substrate BS. The circuit layer DP-CL may include a light-shielding electrode BML, the transistor TR, a connection electrode CNE, and a plurality of insulating layers BFL and INS1 to INS6. The insulating layers BFL and INS1 to INS6 may include a buffer layer BFL and first, second, third, fourth, fifth, and sixth insulating layers INS1, INS2, INS3, INS4, INS5, and INS6. However, the stack structure of the circuit layer DP-CL shown in FIG. 9 is merely one of embodiments, and thus, may be changed in various ways depending on the configuration of the display panel DP and the processes for the circuit layer DP-CL.

The light-shielding electrode BML may be disposed on the base substrate BS. The light-shielding electrode BML may overlap the transistor TR. The light-shielding electrode BML may block light entering the transistor TR from a lower side of the display panel DP to protect the transistor TR. The light-shielding electrode BML may include a conductive material. When voltage is applied to the light-shielding electrode BML, a threshold voltage of the transistor TR disposed on the light-shielding electrode BML may be maintained, however, the disclosure should not be limited thereto or thereby. In an embodiment, the light-shielding electrode BML may be a floating electrode. In an embodiment, the light-shielding electrode BML may be omitted.

The buffer layer BFL may be disposed on the base substrate BS to cover the light-shielding electrode BML. The buffer layer BFL may be an inorganic layer. The buffer layer BFL may improve an adhesion between a semiconductor pattern disposed on the buffer layer BFL and the base substrate BS or between a conductive pattern and the base substrate BS.

The transistor TR may include a source S1, a channel C1, a drain D1, and a gate G1. The source S1, the channel C1, and the drain D1 of the transistor TR may be formed from the semiconductor pattern. The semiconductor pattern of the transistor TR may include polysilicon, amorphous silicon, or a metal oxide and should not be particularly limited as long as a material for the semiconductor pattern of the transistor TR has a semiconductor property.

The semiconductor pattern may include a plurality of portions distinguished from each other depending on a level of conductivity. A portion of the semiconductor pattern, which is doped with a dopant, or a portion of the semiconductor pattern, where a metal oxide is reduced, may have a relatively high conductivity and may serve as a source electrode and a drain electrode of the transistor TR. The portion of the semiconductor pattern, which has a relatively high conductivity, may correspond to the source S1 and the drain D1 of the transistor TR. A non-doped portion, a portion doped at low-concentration, or a portion where the metal oxide is not reduced, which is provided with a relatively low conductivity, may correspond to the channel C1 (or an active) of the transistor TR.

The first insulating layer INS1 may be disposed on the buffer layer BFL and may cover the semiconductor pattern of the transistor TR. The gate G1 of the transistor TR may be disposed on the first insulating layer INS1. The gate G1 may overlap the channel C1 of the transistor TR. The gate G1 may be used as a mask in a process of doping the semiconductor pattern of the transistor TR.

The second insulating layer INS2 may be disposed on the first insulating layer INS1 and may cover the gate G1. The third insulating layer INS3 may be disposed on the second insulating layer INS2.

The connection electrodes CNE may include a first connection electrode CNE1 and a second connection electrode CNE2 to electrically connect the transistor TR and the light-emitting element ED. However, the configuration of the connection electrode CNE that connects the transistor TR and the light-emitting element ED should not be limited thereto or thereby. In an embodiment, one of the first and second connection electrodes CNE1 and CNE2 may be omitted, or the connection electrode CNE may further include an additional connection electrode.

The first connection electrode CNE1 may be disposed on the third insulating layer INS3. The first connection electrode CNE1 may be connected to the drain D1 via a first contact hole CH1 defined through the first to third insulating layers INS1 to INS3. The fourth insulating layer INS4 may be disposed on the third insulating layer INS3 and may cover the first connection electrode CNE1. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 via a second contact hole CH2 defined through the fourth and fifth insulating layers INS4 and INS5. The sixth insulating layer INS6 may be disposed on the fifth insulating layer INS5 and may cover the second connection electrode CNE2.

Each of the first to sixth insulating layers INS1 to INS6 may include an inorganic layer or an organic layer. In an embodiment, the inorganic layer may include at least one of aluminum oxide, titanium oxide, silicon oxide, silicon oxynitride, zirconium oxide, and hafnium oxide. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

A display element layer DP-EL may include a pixel definition layer PDL and the light-emitting element ED. The light-emitting element ED may include a first electrode AE, a hole control layer HCL, a light-emitting layer EML, an electron control layer TCL, and a second electrode CE. The second electrode CE may be disposed on the first electrode AE. The light-emitting layer EML may be disposed between the first electrode AE and the second electrode CE. The hole control layer HCL may be disposed between the first electrode AE and the light-emitting layer EML. The electron control layer TCL may be disposed between the light-emitting layer EML and the second electrode CE.

The first electrode AE may be disposed on the sixth insulating layer INS6. The first electrode AE may be connected to the second connection electrode CNE2 via a third contact hole CH3 defined through the sixth insulating layer INS6. The first electrode AE may be connected to the drain D1 of the transistor TR through the first and second connection electrodes CNE1 and CNE2.

The first electrode AE may include or consist of a metal material, a metal alloy, or a conductive compound. The first electrode AE may be an anode or a cathode, however, the disclosure should not be limited thereto or thereby. In addition, the first electrode AE may be a pixel electrode. The first electrode AE may be a transmissive electrode, a transflective electrode, or a reflective electrode. The first electrode AE may include at least one selected from, a compound of two or more selected from, a combination of two or more selected from, or an oxide of Ag, Mg, Cu, Al, Pt, Pd, Au, Ni, Nd, Ir, Cr, Li, Ca, LiF, Mo, Ti, W, In, Sn, and Zn.

When the first electrode AE is the transmissive electrode, the first electrode AE may include a transparent metal oxide, e.g., indium tin oxide (“ITO”), indium zinc oxide (“IZO”), zinc oxide (ZnO), indium tin zinc oxide (“ITZO”), or the like. When the first electrode AE is the transflective or reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, any combinations thereof, or any combinations thereof, e.g., a combination of Ag and Mg. The first electrode AE may have a multi-layer structure of a reflective layer or a transflective layer, which includes or consists of the above-mentioned material, and a transparent conductive layer including or consisting of indium tin oxide (“ITO”), indium zinc oxide (“IZO”), zinc oxide (ZnO), indium tin zinc oxide (“ITZO”), or the like. In an embodiment, the first electrode AE may have a three-layer structure of ITO/Ag/ITO, however, it should not be limited thereto or thereby. In an embodiment, the first electrode AE may include the metal materials, a combination of two or more of the metal materials, or an oxide of the metal materials.

The pixel definition layer PDL may be disposed on the sixth insulating layer INS6. A light-emitting opening PX_OP may be defined through the pixel definition layer PDL to expose a portion of the first electrode AE. The portion of the first electrode AE exposed through the light-emitting opening PX_OP may correspond to a light-emitting area LA.

The display area DM-DA of the display module DM may include the light-emitting area LA and a non-light-emitting area NLA. An area in which the pixel definition layer PDL is disposed may correspond to the non-light-emitting area NLA. The non-light-emitting area NLA may surround the light-emitting area LA in the display area DM-DA.

The hole control layer HCL may be disposed on the first electrode AE and the pixel definition layer PDL. The hole control layer HCL may be provided as a common layer that overlaps the light-emitting area LA and the non-light-emitting area NLA. Contrary to what is illustrated in FIG. 9, the hole control layer HCL may be disposed in an area corresponding to the light-emitting opening PX_OP. The hole control layer HCL may include at least one of a hole transport layer, a hole injection layer, and an electron block layer. The hole control layer HCL may include a known hole injection material and/or a known hole transport material.

The light-emitting layer EML may be disposed on the hole control layer HCL. The light-emitting layer EML may be disposed in the area corresponding to the light-emitting opening PX_OP. However, the disclosure should not be limited thereto or thereby, and the light-emitting layer EML may be provided as a common layer. The light-emitting layer EML may include an organic light-emitting material and/or an inorganic light-emitting material. The light-emitting layer EML may emit a light having one of red, green, and blue colors. In an embodiment, the light-emitting layer EML may emit a blue light.

The electron control layer TCL may be disposed on the light-emitting layer EML. The electron control layer TCL may be provided as a common layer that overlaps the light-emitting area LA and the non-light-emitting area NLA. Contrary to what is illustrated in FIG. 9, the electron control layer TCL may be disposed in the area corresponding to the light-emitting opening PX_OP. The electron control layer TCL may include at least one of an electron transport layer, an electron injection layer, and a hole block layer. The electron control layer TCL may include a known electron injection material and/or a known electron transport material.

The second electrode CE may be disposed on the electron control layer TCL. The second electrode CE may be provided as a common layer that overlaps the light-emitting area LA and the non-light-emitting area NLA. The second electrode CE may be a common electrode. The second electrode CE may be a cathode or an anode. In an embodiment, when the first electrode AE is the anode, the second electrode CE may be the cathode, and when the first electrode AE is the cathode, the second electrode CE may be the anode.

The second electrode CE may be a transmissive electrode, a transflective electrode, or a reflective electrode. In the case where the second electrode CE is the transmissive electrode, the second electrode CE may include a transparent metal oxide, e.g., indium tin oxide (“ITO”), indium zinc oxide (“IZO”), zinc oxide (ZnO), indium tin zinc oxide (“ITZO”), etc.

In the case where the second electrode CE is the transflective electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, any combinations thereof, e.g., AgMg, AgYb, or MgYb. In addition, the second electrode CE may have a multi-layer structure of a reflective layer or a transflective layer, which includes or consists of the above-mentioned material, and a transparent conductive layer including or consisting of indium tin oxide (“ITO”), indium zinc oxide (“IZO”), zinc oxide (ZnO), or indium tin zinc oxide (“ITZO”). In an embodiment, the second electrode CE may include the above-mentioned metal materials, a combination of two or more metal materials selected from the above-mentioned metal materials, or an oxide of the above-mentioned metal materials.

An encapsulation layer TFE may be disposed on the second electrode CE to cover the light-emitting element ED. The encapsulation layer TFE may include a plurality of thin layers. In an embodiment, the encapsulation layer TFE may include inorganic layers disposed on the second electrode CE and an organic layer disposed between the inorganic layers. The inorganic layer may protect the light-emitting element ED from moisture and oxygen, and the organic layer may protect the light-emitting element ED from a foreign substance such as dust particles.

The input sensing part TP may include a first sensing insulating layer IL1, a second sensing insulating layer IL2, and a third sensing insulating layer IL3. The input sensing part TP may include at least one conductive layer disposed on the sensing insulating layers. The input sensing part TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may contact the encapsulation layer TFE, however, the disclosure should not be limited thereto or thereby. In an embodiment, the first sensing insulating layer IL1 may be omitted, and in this case, the first conductive layer CDL1 may contact the encapsulation layer TFE.

The first conductive layer CDL1 may be disposed on the first sensing insulating layer IL1. The first conductive layer CDL1 may include a plurality of first conductive patterns. The first conductive patterns may be disposed on the first sensing insulating layer IL1. The second sensing insulating layer IL2 may be disposed on the first sensing insulating layer IL1 to cover at least a portion of the first conductive layer CDL1.

The second conductive layer CDL2 may be disposed on the second sensing insulating layer IL2. The second conductive layer CDL2 may include a plurality of second conductive patterns. The second conductive patterns may be disposed on the second sensing insulating layer IL2. The second conductive patterns may be connected to the first conductive patterns via a contact hole defined through the second sensing insulating layer IL2.

Each of the first conductive patterns of the first conductive layer CDL1 and the second conductive patterns of the second conductive layer CDL2 may be arranged corresponding to the non-light-emitting area NLA. Each of the first conductive patterns of the first conductive layer CDL1 and the second conductive patterns of the second conductive layer CDL2 may correspond to a mesh pattern.

The third sensing insulating layer IL3 may be disposed on the second sensing insulating layer IL2 and may cover the second conductive layer CDL2. The second sensing insulating layer IL2 and the third sensing insulating layer IL3 may include an inorganic insulating layer or an organic insulating layer.

Each of the first conductive layer CDL1 and the second conductive layer CDL2 may have a single-layer structure or a multi-layer structure of layers stacked in the third direction DR3. The conductive layers CDL1 and CDL2 having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (“ITO”), indium zinc oxide (“IZO”), zinc oxide (ZnO), indium zinc tin oxide (“ITZO”), or the like. In addition, the transparent conductive layer may include conductive polymer such as poly(3,4-ethylenedioxythiophene) (“PEDOT”), metal nanowire, graphene, or the like.

The conductive layers CDL1 and CLD2 having the multi-layer structure may include metal layers. The metal layers may have a three-layer structure of titanium (Ti)/aluminum (Al)/titanium (Ti). The conductive layers CDL1 and CLD2 having the multi-layer structure may include at least one metal layer and at least one transparent conductive layer.

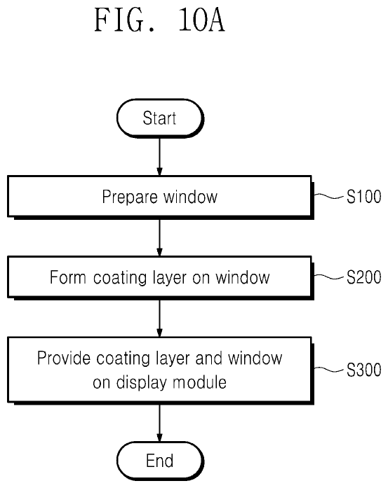

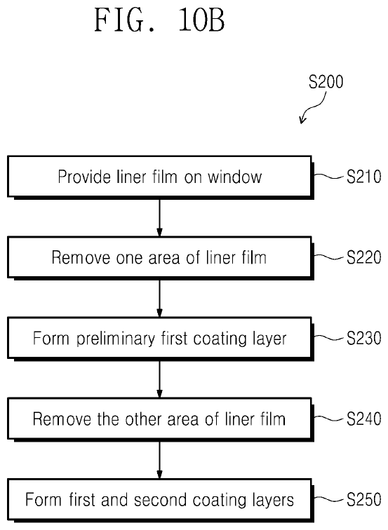

The electronic apparatus may be manufactured through a manufacturing method of the electronic apparatus. FIGS. 10A and 10B are flowcharts showing an embodiment of the manufacturing method of the electronic apparatus of the disclosure. FIGS. 11A to 11F are views showing an embodiment of processes of the manufacturing method of the electronic apparatus of the disclosure. In the description of FIGS. 10A, 10B, and 11A to 11F, descriptions that are the same as those in FIGS. 1 to 9 will not be repeated, and the explanation will focus on differences.

Referring to FIG. 10A, the manufacturing method of the electronic apparatus may include preparing the window including the top surface and the bottom surface disposed between the top surface and the display module and including the concave portion and the flat portion, which are defined in the bottom surface (S100), forming the coating layer including the first coating layer and the second coating layer on the bottom surface of the window (S200), and providing the coating layer and the window on the display module including the folding part and the non-folding part next (adjacent) to the folding part (S300). Referring to FIG. 10B, the forming of the coating layer (S200) may include providing a liner film on the bottom surface of the window (S210), removing one area of the liner film (S220), providing the first resin composition in the concave portion and irradiating a first light to the first resin composition to form a preliminary first coating layer (S230), removing a remaining (the other) area of the liner film (S240), and providing the second resin composition on the flat portion and irradiating a second light to form the first coating layer and the second coating layer (S250).

Referring to FIG. 11A, the liner film LFM including the one area (also referred to as a first area) LMA1 that overlaps with the concave portion CVP and a remaining (the other) area (also referred to as a second area) LMA2 that overlaps with the flat portion FLP may be provided on the bottom surface BT_S of the window WD including the concave portion CVP and the flat portion FLP. The one area LMA1 may overlap with the folding part FP-D (refer to FIG. 4) of the display module DM (refer to FIG. 4). A remaining (the other) area LMA2 may overlap with the non-folding parts NFP1-D and NFP2-D (refer to FIG. 4) of the display module DM (refer to FIG. 4). Referring to FIGS. 11B and 11C, the one area LMA1 of the liner film LFM, which overlaps with the concave portion CVP, may be removed, and the first resin composition COP-1 may be provided in the concave portion CVP. A liner film LFM-1 from which the one area LMA1 is removed may include only a remaining (the other) area LMA2. The first resin composition COP-1 may be provided to have a thickness equal to a sum of a depth in the third direction DR3 of the concave portion CVP and a thickness in the third direction DR3 of the liner film LFM-1. The liner film LFM-1 may allow the first resin composition COP-1 to be provided only in the concave portion CVP and may prevent the first resin composition COP-1 from overflowing to the flat portion FLP.

Referring to FIGS. 11C and 11D, the first light LL1 may be provided to the first resin composition COP-1 to form the preliminary first coating layer P_CTL1. The preliminary first coating layer P_CTL1 formed by the first light LL1 may be in a semi-cured state. The preliminary first coating layer P_CTL1 in the semi-cured state may maintain its shape in the concave portion CVP without flowing even when the liner film LFM-1 is removed. Accordingly, the manufacturing method of the electronic apparatus may provide excellent processability.

Then, a remaining (the other) area LMA2 of the liner film LFM-1, which overlaps with the flat portion FLP, may be removed, and the second resin composition COP-2 may be provided on the flat portion FLP. The second resin composition COP-2 may be provided to a thickness equal to the thickness in the third direction DR3 of the liner film LFM. Referring to FIGS. 11E and 11F, the second light LL2 may be provided to the preliminary first coating layer P_CTL1 and the second resin composition COP-2 to form the first coating layer CTL1 and the second coating layer CTL2. Then, the coating layer CTL, which includes the first coating layer CTL1 and the second coating layer CTL2, and the window WD may be provided on the display module DM (refer to FIG. 5) including the folding part FP-D (refer to FIG. 4) and the non-folding parts NFP1-D and NFP2-D (refer to FIG. 4) next (adjacent) to the folding part FP-D (refer to FIG. 4).

The first coating layer CTL1 may include a first polymer derived from the first resin composition COP-1. The second coating layer CTL2 may include a second polymer derived from the second resin composition COP-2. The first polymer may be different from the second polymer. The first and second coating layers CTL1 and CTL2 may be formed by adjusting the crosslink density of the first and second resin compositions COP-1 and COP-2 differently or by adjusting a composition ratio of monomers and/or oligomers included in the first and second resin compositions COP-1 and COP-2 differently.

Each of the first resin composition COP-1 and the second resin composition COP-2 may include at least one of an acrylic resin, a urethane resin, and a silicone resin. However, this is merely one of embodiments, and the first resin composition COP-1 and the second resin composition COP-2 should not be limited thereto or thereby.

The difference between the dispersion force of the first resin composition COP-1 and the dispersion force of the window WD may be greater than or equal to 8 and smaller than or equal to 13, and the difference between the dispersion force of the second resin composition COP-2 and the dispersion force of the window WD may be greater than or equal to 8 and smaller than or equal to 13. As described above, when the difference between the dispersion force of the first and second resin compositions COP-1 and COP-2 and the dispersion force of the window WD is greater than or equal to 8 and smaller than or equal to 13, the first and second resin compositions COP-1 and COP-2 have the surface tension similar to that of the window WD, and the electronic apparatus manufactured including the first and second resin compositions COP-1 and COP-2 may have excellent display quality.

In FIGS. 11B and 11D, the first and second resin compositions COP-1 and COP-2 are illustrated as being provided through a nozzle NZ, but devices to provide the first and second resin compositions COP-1 and COP-2 should not be limited to the nozzle NZ. In FIGS. 11C and 11E, the first light LL1 and second light LL2 may be an ultraviolet light. However, this is merely one of embodiments, and the disclosure should not be limited thereto or thereby.

The forming of the coating layer CTL may include forming the tackifier layer TKL (refer to FIG. 7). The forming of the tackifier layer TKL (refer to FIG. 7) may include dispersing the oligomer (tackifier) including an alkyl group having 5 carbon atoms to 20 carbon atoms in its side chain in the first resin composition COP-1, moving the tackifier to the concave portion CVP during the irradiating of the first light LL1, and curing the tackifier after the irradiating of the second light LL2.

In the first resin composition COP-1, the composition excluding the tackifier may be cured during the irradiating of the first light LL1 and second light LL2 to form the elastic layer ELL (refer to FIG. 7). In this case, the tackifier does not participate in the crosslinking of the composition and may move to the concave portion CVP. Subsequently, the tackifier may be cured independently of the elastic layer ELL (refer to FIG. 7) to form the tackifier layer TKL (refer to FIG. 7). As described above, since the tackifier layer TKL (refer to FIG. 7) includes the alkyl group having 5 carbon atoms to 20 carbon atoms in its side chain and has the glass transition temperature greater than or equal to 80 °C and smaller than or equal to 120 °C, the tackifier layer TKL may have improved adhesion without being delaminated even at relatively high temperatures. Accordingly, the electronic apparatus including the tackifier layer TKL (refer to FIG. 7) may have excellent reliability.

Although the embodiments of the disclosure have been described, it is understood that the disclosure should not be limited to these embodiments but various changes and modifications may be made by one ordinary skilled in the art within the spirit and scope of the disclosure as hereinafter claimed.

Therefore, the disclosed subject matter should not be limited to any single embodiment described herein, and the scope of the inventive concept shall be determined according to the attached claims.

What is claimed is:

1. An electronic apparatus comprising:
a display module comprising a folding part and a non-folding part next to the folding part;
a window comprising:
a top surface; and
a bottom surface disposed between the top surface and the display module and disposed on the display module, the bottom surface comprising:
a concave portion which overlaps with the folding part and is concave downward; and
a flat portion which overlaps with the non-folding part;
a coating layer disposed between the display module and the window, the coating layer comprising:
a first coating layer being in contact with the concave portion and the display module, the first coating layer comprising:
a tackifier layer derived from an oligomer comprising an alkyl group having 5 carbon atoms to 20 carbon atoms and has a storage modulus smaller than or equal to about 0.1 megapascal at room temperature; and
a second coating layer being in contact with the flat portion and the display module and having a tensile modulus greater than or equal to about 1 megapascal and smaller than or equal to about 100 megapascals at room temperature.

2. The electronic apparatus of claim 1, wherein a difference between a refractive index of the window and a refractive index of the coating layer is smaller than or equal to about 0.2.

3. The electronic apparatus of claim 1, wherein the first coating layer has a thickness greater than or equal to about 60 micrometers and smaller than or equal to about 120 micrometers, and the second coating layer has a thickness greater than or equal to about 10 micrometers and smaller than or equal to about 30 micrometers.

4. The electronic apparatus of claim 1, wherein a thickness of the first coating layer is greater than a thickness of the second coating layer.

5. The electronic apparatus of claim 1, wherein a sum of a thickness of the concave portion and a thickness of the first coating layer is equal to a sum of a thickness of the flat portion and a thickness of the second coating layer.

6. The electronic apparatus of claim 1, wherein the first coating layer comprises a polymer derived from a first resin composition comprising the oligomer, and the second coating layer comprises a polymer derived from a second resin composition comprising the oligomer.

7. The electronic apparatus of claim 1, wherein the oligomer has a glass transition temperature greater than or equal to 80 degrees Celsius and smaller than or equal to 120 degrees Celsius.

8. The electronic apparatus of claim 1, wherein a creep measured 1 hour after a manufacturing time point of the coating layer is greater than or equal to 0.05 times and smaller than or equal to 0.2 times of a creep measured at the manufacturing time point of the coating layer.

9. The electronic apparatus of claim 1, wherein the coating layer has a recovery rate greater than or equal to about 90% after undergoing 100 cycles of tensile tests.

10. The electronic apparatus of claim 1, wherein the first coating layer further comprises an elastic layer, the tackifier layer contacts the concave portion of the window, and the elastic layer is disposed between the tackifier layer and the display module.

11. The electronic apparatus of claim 1, wherein the top surface of the window is flat.

12. A method of manufacturing an electronic apparatus, the method comprising:
preparing a window comprising a top surface and a bottom surface disposed between the top surface and a display module and comprising a concave portion and a flat portion, which are defined in the bottom surface, before providing a coating layer and the window on the display module comprising a folding part and a non-folding part next to the folding part; and
forming the coating layer comprising a first coating layer and a second coating layer on the bottom surface of the window,
wherein the concave portion is concave downward and overlaps with the folding part, and the flat portion overlaps with the non-folding part, and
the forming the coating layer comprises:
providing a liner film comprising a first area overlapping with the concave portion and a second area overlapping the flat portion on the bottom surface of the window;
removing the first area of the liner film;
providing a first resin composition in the concave portion and irradiating a first light to the first resin composition to form a preliminary first coating layer;
removing the second area of the liner film; and
providing a second resin composition on the flat portion and irradiating a second light to form the first coating layer and the second coating layer.

13. The method of claim 12, wherein the first coating layer comprises a tackifier layer derived from an oligomer comprising an alkyl group having 5 carbon atoms to 20 carbon atoms.

14. The method of claim 13, wherein the forming the coating layer comprises forming the tackifier layer, and the forming the tackifier layer comprises:
providing the first resin composition comprising the oligomer;
moving the oligomer to the concave portion during the irradiating the first light; and
curing the oligomer after the irradiating the second light.

15. The method of claim 13, wherein the oligomer has a glass transition temperature greater than or equal to 80 degrees Celsius and smaller than or equal to 120 degrees Celsius.

16. The method of claim 13, wherein the first coating layer further comprises an elastic layer, the tackifier layer contacts the concave portion of the window, and the elastic layer is disposed between the tackifier layer and the display module.

17. The method of claim 12, wherein the first resin composition is provided with a thickness equal to a sum of a depth of the concave portion and a thickness of the liner film, and the second resin composition is provided with a thickness equal to the thickness of the liner film.

18. The method of claim 12, wherein a difference between a dispersion force of the first resin composition and a dispersion force of the window is greater than or equal to 8 and smaller than or equal to 13, and a difference between a dispersion force of the second resin composition and the dispersion force of the window is greater than or equal to 8 and smaller than or equal to 13.

19. The method of claim 12, wherein the first coating layer has a thickness greater than or equal to about 60 micrometers and smaller than or equal to about 120 micrometers, and the second coating layer has a thickness greater than or equal to about 10 micrometers and smaller than or equal to about 30 micrometers.

20. The method of claim 12, wherein the first coating layer has a storage modulus smaller than or equal to about 0.1 megapascal at room temperature, and the second coating layer has a tensile modulus greater than or equal to about 1 megapascal and smaller than or equal to about 100 megapascals at room temperature.
